(19) United States
(12) Patent Application Publication
(10) Pub. No.: US 2026/0063691 A1
(43) Pub. Date: Mar. 5, 2026

(54) SHUNT RESISTOR AND POWER METER WITH INTEGRATED FEATURES THEREOF

(71) Applicant: Accuenergy (Canada) Inc., Toronto (CA)

(72) Inventors: Yufan Wang, Toronto (CA); Shaohang Cui, Toronto (CA); Ketao Li, Toronto (CA); Liang Wang, Toronto (CA)

(73) Assignee: Accuenergy (Canada) Inc., Toronto (CA)

(21) Appl. No.: 18/825,021

(22) Filed: Sep. 5, 2024

(51) Int. Cl. G01R 22/06; G01R 15/14

(52) U.S. Cl. CPC G01R 22/065; G01R 15/146

(57) ABSTRACT

A shunt resistor and power meter with integrated features thereof. The shunt resistor comprises a resistance element with recessed portions on opposite sides, reducing stress concentration and thermal expansion differences. First and second electrodes connect to the resistance element's ends, with measurement terminals attached. The recessed portions extend perpendicular to the resistor's length, enhancing performance. A power meter incorporates this shunt resistor, mounted on a support platform within a shunt part. The meter part computes energy consumption based on voltage signals from the shunt resistor. A protective cover encloses both parts. This design improves accuracy, thermal management, and adaptability in current measurement applications, particularly suitable for high-current scenarios like electric vehicle charging stations.

### FIELD OF THE INVENTION

The present disclosure relates to a shunt resistor and a power meter including the shunt resistor.

### BACKGROUND

In the field of electrical engineering and power management, accurate current measurement is crucial for a wide range of applications, from industrial processes to emerging technologies such as electric vehicle charging stations. Shunt resistors have long been a fundamental component in current measurement systems due to their reliability and precision. However, as the demand for higher current capacities and more accurate measurements increases, traditional shunt resistor designs face several limitations.

Conventional shunt resistors often struggle with issues related to heat dissipation, stress concentration, and thermal expansion, particularly when dealing with high currents. These problems can lead to measurement inaccuracies, reduced lifespan of the components, and in some cases, safety concerns. Additionally, the integration of shunt resistors into comprehensive power measurement systems has traditionally been complex, often requiring separate components and intricate wiring, which can introduce further sources of error and increase installation complexity.

Power meters, which rely on accurate current measurements provided by shunt resistors, face their own set of challenges. Many existing power meter designs are bulky, difficult to install, and lack the flexibility to adapt to varying current ranges without complete replacement. This inflexibility can lead to increased costs and downtime in industrial and commercial settings where power monitoring needs may change over time.

There is a clear need in the industry for an improved shunt resistor design that can address the issues of heat dissipation, stress concentration, and thermal expansion, particularly for high-current applications.

### SUMMARY OF THE INVENTION

The present invention relates to an advanced shunt resistor for current measurement and an innovative power meter that incorporates this shunt resistor, providing significant improvements in accuracy, thermal management, and adaptability for various current measurement applications.

The shunt resistor of the present invention comprises a resistance element with a first and second end, connected to a first and second electrode respectively. A key feature of this resistor is the inclusion of recessed portions on opposite side surfaces of the resistance element. These recessed portions extend inward towards the center of the shunt resistor and are specifically designed to reduce stress concentration and mitigate thermal expansion differences. This novel design enhances the resistor's stability and accuracy under varying temperature conditions, which is crucial for high-current applications.

The first and second electrodes are arranged in a first direction corresponding to the length of the shunt resistor. Perpendicular to this, in a second direction, the recessed portions extend, creating a unique cross-sectional profile that optimizes the resistor's performance. This arrangement allows for improved heat dissipation and more uniform current distribution throughout the resistance element.

The shunt resistor features two measurement terminals: a first measurement terminal attached to the first electrode and a second measurement terminal attached to the second electrode. These terminals are designed to provide accurate voltage signals that are proportional to the current flowing through the shunt resistor.

The first measurement terminal has a distinctive design, comprising a base part that lies parallel to the surface of the shunt resistor, two electrical connector pins that extend perpendicular to this surface, and a support part that connects the base to the connector pins. This configuration allows for robust electrical connections and facilitates integration with external measurement circuits.

In contrast, the second measurement terminal has a similar structure but with only one electrical connector pin. This asymmetrical design of the measurement terminals contributes to the overall versatility of the shunt resistor, allowing it to be easily integrated into various circuit configurations.

To further enhance the shunt resistor's thermal management capabilities, a heat sink is positioned above the front surface of the resistor. Importantly, an insulating film is interposed between the heat sink and the shunt resistor. This insulating layer is critical for maintaining measurement accuracy by preventing any electrical interference from the metallic heat sink while still allowing efficient heat dissipation.

The recessed portions of the resistance element are designed to be rectangular when viewed perpendicular to both the length and width directions of the shunt resistor. This geometry contributes to the overall stress reduction and improved thermal characteristics of the device.

Material selection plays a crucial role in the performance of the shunt resistor. The first and second electrodes are preferably made of copper, chosen for its excellent electrical conductivity. The resistance element itself is constructed from a Cu-Mn alloy, which provides a good balance of low resistance and temperature stability.

To facilitate connection with bus bars for high-current applications, the first and second electrodes each include at least one opening. These openings are designed to accommodate large conductors, enabling the shunt resistor to be easily integrated into high-power electrical systems.

The invention also encompasses a power meter that incorporates the advanced shunt resistor described above. This power meter is specifically designed for installation on a standard DIN rail, making it highly compatible with existing electrical infrastructure.

The power meter consists of three main components: a shunt part, a meter part, and a protective cover. The shunt part includes the shunt resistor mounted on a support platform. This platform is designed to securely hold the shunt resistor while also facilitating its integration with the rest of the power meter.

The meter part is configured to compute the electric energy consumed by an electrically powered device. It does this by processing the voltage signals received from the shunt resistor. This integration of the shunt resistor and computational electronics in a single unit represents a significant advancement in power measurement technology.

A key feature of the power meter's design is the integral formation of the support platform and the meter part. This unified structure enhances the overall structural integrity of the device and simplifies its installation on the DIN rail. The result is a more robust and easier-to-deploy power measurement solution.

The support platform of the power meter includes two rectangular openings, specifically designed to accommodate the measurement terminals of the shunt resistor. The first opening is larger and configured to accommodate the first measurement terminal with its two electrical connector pins. The second opening is smaller, designed for the second measurement terminal with its single connector pin. This precise configuration ensures secure and accurate connections between the shunt resistor and the meter's circuitry.

The protective cover of the power meter is an integral part of its design, enclosing both the shunt part and the meter part. This cover is detachable and U-channel shaped, comprising a left part that encases the support platform and right parts that protect the meter part. The detachable nature of the cover allows for easy access during installation, maintenance, or replacement of the shunt resistor.

To address thermal management concerns, the left part of the cover incorporates through holes arranged in a grid pattern. These holes facilitate heat dissipation from the shunt resistor, ensuring that the device maintains accuracy and reliability even under high-current conditions.

For easy installation and removal, the power meter includes a clip for mounting onto the DIN rail. This clip is designed to facilitate quick attachment and detachment, simplifying the process of installing or replacing the power meter in electrical panels or enclosures.

Inside the power meter, a multi-layer printed circuit board (PCB) is housed within the support platform and meter part. The measurement terminals of the shunt resistor are fastened directly to this PCB, ensuring reliable electrical connections and signal integrity. This integrated design minimizes potential points of failure and contributes to the overall accuracy of the power measurements.

One of the most innovative features of this power meter is the replaceability of the shunt resistor. This design allows for adaptation to various current ranges without needing to replace the entire power meter. Users can select and install the appropriate shunt resistor for their specific current measurement needs, greatly enhancing the versatility and longevity of the power meter.

In conclusion, this invention presents a comprehensive solution for accurate and reliable current measurement and power metering. The advanced shunt resistor design, with its stress-reducing recessed portions and efficient thermal management, addresses key challenges in high-current measurement applications. Its integration into a modular, DIN rail-mountable power meter represents a significant advancement in the field of electrical power measurement. The combined features of accuracy, adaptability, ease of installation, and maintenance make this invention particularly suitable for a wide range of applications, from industrial power monitoring to advanced energy management systems in smart grids and electric vehicle charging infrastructure.

### BRIEF DESCRIPTION OF THE DRAWINGS

FIG. 1 is a rear perspective view of a shunt resistor according to some embodiments of the present invention.

FIG. 2 is a plan rear view of a shunt resistor according to some embodiments of the present invention.

FIG. 3 is a front perspective view of a shunt resistor according to some embodiments of the present invention.

FIG. 4 is a front view of a shunt resistor according to some embodiments of the present invention.

FIG. 5 is an enlarged view of the measurement terminals depicted in FIG. 1

FIG. 6 is a wiring diagram of a power meter according to some embodiments of the present invention.

FIG. 7 is a wiring diagram of a power meter in prior art.

FIG. 8 is a front perspective view of a current detection device according to some embodiments of the present invention.

FIG. 9 is a front perspective view of a current detection device according to some embodiments of the present invention.

FIG. 10 is a rear view of a current detection device according to some embodiments of the present invention.

FIG. 11 is a front perspective view of a cover component of a current detection device according to some embodiments of the present invention.

FIG. 12 is a rear perspective view of a cover component of a current detection device according to some embodiments of the present invention.

FIG. 13 is a current detection device with a cover component removed according to some embodiments of the present invention.

### DETAILED DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

Herein the terms “front,” “rear,” “up,” “down,” “right,” and “left” are relative terms used to describe the orientation or direction of components, primarily for the ease of understanding the invention. They serve as spatial references to facilitate the description and are generally defined in relation to the figures presented in the drawings. It's essential to note that these terms are not intended to limit the invention to any specific orientation or spatial configuration unless explicitly stated.

In most cases, the use of these terms is standardized to match the orientation as presented in the drawings accompanying the patent application. However, the terms are relative to the “viewer” or the point of view in the drawings, and not necessarily indicative of a fixed spatial orientation in real-world use of the invention.

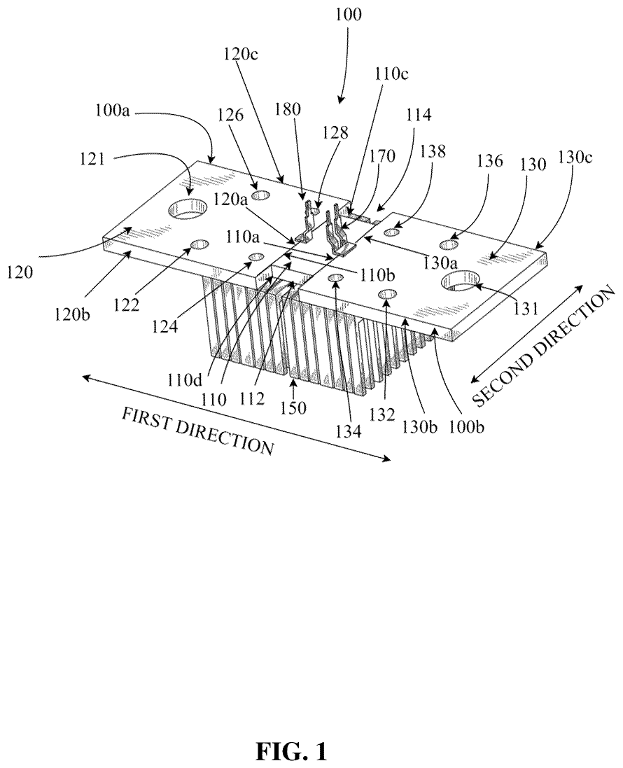

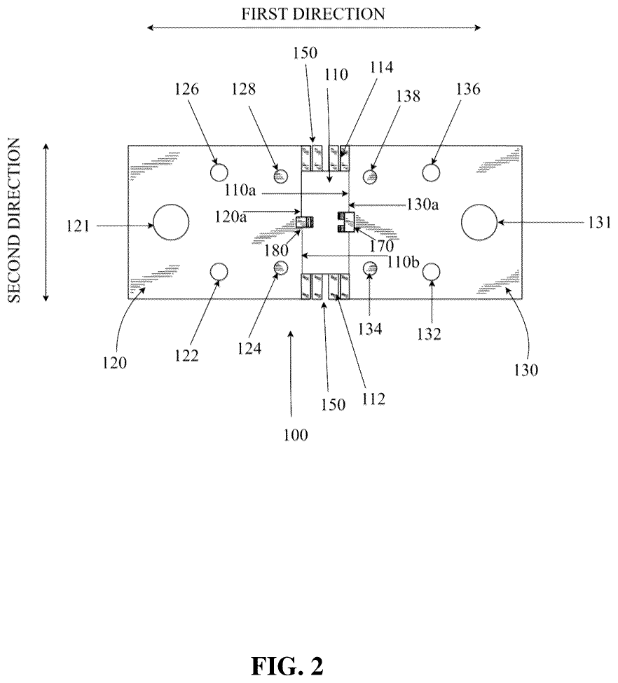

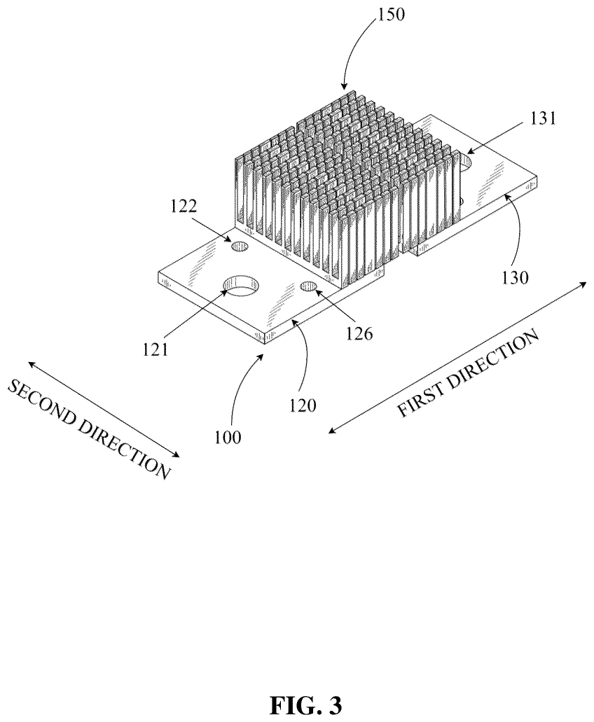

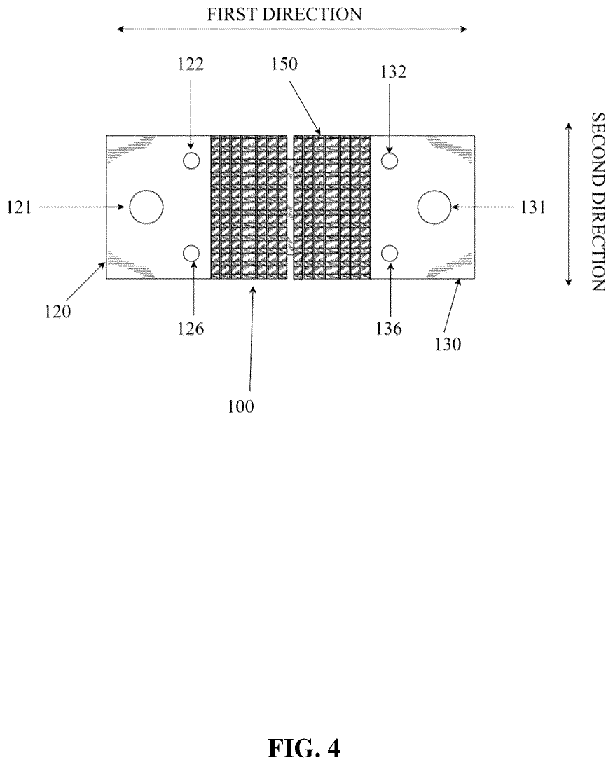

FIG. 1 is a rear perspective view showing one embodiment of a shunt resistor 100, and FIG. 2 is a plan rear view of the shunt resistor 100 shown in FIG. 1. FIG. 3 is a front perspective view showing one embodiment of the shunt resistor 100, and FIG. 4 is a plan front view of the shunt resistor 100 shown in FIG. 3.

As illustrated in FIGS. 1-4, the shunt resistor 100 comprises a resistance element 110, which is fabricated from a resistor alloy plate material of predetermined thickness and width.

This element is accompanied by a pair of electrodes, 120 and 130, constructed from a highly conductive metal, each electrode being affixed to opposite ends (i.e., connecting surfaces) 110a and 110b of the resistance element 110 in a first direction. Electrode 120 features a contact surface 120a that interfaces with one end (110b) of the resistance element 110, while electrode 130 includes a contact surface 130a that interfaces with the other end (110a) of the resistance element 110. Additionally, the electrodes 120 and 130 are equipped with bolt holes 122, 124, 126, 128, 132, 134, 136, and 138, respectively, facilitating the attachment of the shunt resistor 100 via screws or similar fastening mechanisms.

The first direction refers to the length direction of the resistance element 110, corresponding to the overall length direction of the shunt resistor 100. This length direction is defined by the sequential arrangement of electrode 120, resistance element 110, and electrode 130. Perpendicular to this first direction is the second direction, which corresponds to the width direction of the shunt resistor 100. As depicted in FIGS. 1-4, the electrodes 120 and 130 are identical in structure and are basically symmetrically positioned relative to the resistance element 110.

The connecting surfaces 110a and 110b of the resistance element 110 are bonded to the electrodes 120 and 130 through welding techniques, such as electron beam welding, laser beam welding, or brazing. The resistance element 110 is typically constructed from a low-resistance alloy material, for example, a Cu—Mn alloy. The electrodes 120 and 130 are preferably made of copper (Cu) to ensure high conductivity and minimal contact resistance.

As depicted in FIGS. 1-4, the shunt resistor 100 features recessed portions 114 and 112 on opposite side surfaces 100a and 100b, respectively. The recessed portion 114 is formed on side surface 100a and extends inward towards the center of the shunt resistor 100, while the recessed portion 112 is formed on side surface 100b and also extends inward towards the center of the shunt resistor 100. Both recessed portions 114 and 112 extend in the same direction, identified as the second direction. When viewed from above, perpendicular to both the first and second directions, the recessed portions 114 and 112 exhibit a rectangular shape.

Side surface 100a of the shunt resistor 100 is parallel to the first direction and comprises side surfaces 120c and 130c of electrodes 120 and 130, respectively. Similarly, side surface 100b, which is opposite side surface 100a, is also parallel to the first direction and comprises side surfaces 120b and 130b of electrodes 120 and 130, respectively. The side surface 120c of electrode 120 is aligned on an extension line with the side surface 130c of electrode 130, and side surface 120b of electrode 120 is aligned on an extension line with the side surface 130b of electrode 130. Side surfaces 120b and 130b are parallel to side surfaces 120c and 130c.

The recessed portion 112 features a side surface 110d of the resistance element 110, which is parallel to the first direction. Similarly, recessed portion 114 features a side surface 110c of the resistance element 110, also parallel to the first direction. The recessed portion 112 is bounded by side surfaces 110d, 110a, and 110b, while recessed portion 114 is bounded by side surfaces 110c, 110a, and 110b.

The recessed portions 112 and 114 reduce stress concentration and thermal expansion differences, ensuring stable performance under varying temperature conditions. The materials and precise alignment of the electrodes and resistance element are selected to enhance conductivity and minimize resistance variability, thereby improving the overall accuracy of current measurement.

Electrode 120 features an opening 121 on its left side, while electrode 130 incorporates a corresponding opening 131 on its right side. These openings are configured to facilitate connection with bus bars, enabling the transmission of input and output current signals that are subsequently measured by the shunt resistor 100.

As illustrated in FIG. 3, a heat sink 150 is positioned above the front surface of the shunt resistor 100. Critically, an insulating film is interposed between the heat sink 150 and the shunt resistor 100. This insulating layer serves a vital function in maintaining measurement accuracy by electrically isolating the metallic heat sink from the shunt, thereby preventing any interference with the current measurement.

The heat sink 150 is characterized by a dense array of parallel, vertically-oriented fins extending upward from a common base. These fins, uniformly spaced, cover the majority of the shunt's upper surface, creating a substantially rectangular footprint when viewed from above.

This design significantly augments the surface area available for heat dissipation, a critical factor in managing the thermal energy generated during the shunt's operation.

Fabricated from highly thermally conductive materials such as aluminum or copper, the heat sink 150 ensures optimal heat dissipation. Its design, in conjunction with the insulating film, forms an integral part of the shunt's thermal management system. This configuration potentially enables enhanced performance characteristics including higher current capacity and improved measurement accuracy through the mitigation of temperature-related effects, while maintaining electrical isolation.

FIG. 1 also depicts measurement terminals 170 and 180 positioned in close proximity to the resistive element 110 within electrodes 120 and 130, respectively. These measurement terminals are designed to provide voltage signals directly proportional to the current flowing through the shunt resistor 100, facilitating connection to external circuitry for precise current measurement.

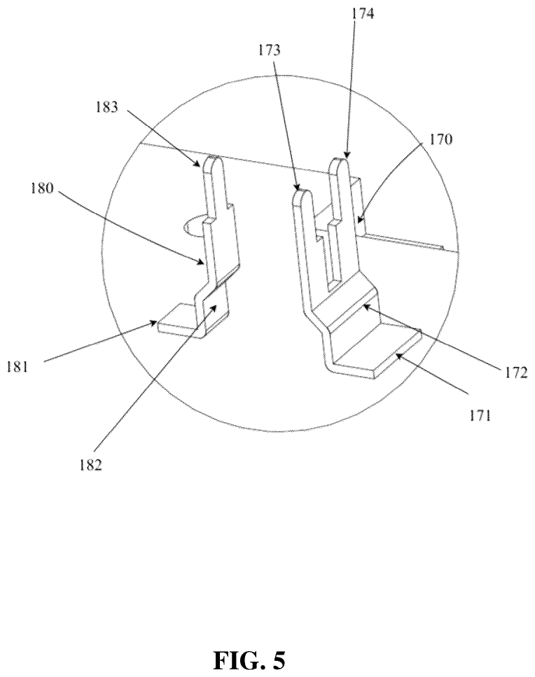

In reference to FIG. 5, which provides an enlarged view of the measurement terminals 170 and 180 depicted in FIG. 1, the present invention introduces a novel design for electrical connections in the shunt resistor 100. The measurement terminal 180 comprises three main components: an electrical connector pin 183, a support part 182, and a base part 181. The base part 181 is configured to lie parallel to the rear surface of the shunt resistor 100 and is affixed thereto through a soldering process. Perpendicular to this rear surface, the electrical connector pin 183 extends vertically, with the support part 182 serving as an intermediary between the pin and the base. Both the junction of the electrical connector pin 183 with the support part 182 and the connection between the support part 182 and the base part 181 are secured through soldering, ensuring robust electrical continuity. All components of this terminal are fabricated from materials exhibiting high electrical conductivity to minimize resistance and enhance

### Measurement Accuracy.

The measurement terminal 170 presents a more complex configuration compared to terminal 180. It incorporates two electrical connector pins, 173 and 174, alongside a support part 172 and a base part 171. Similar to the structure of terminal 180, the base part 171 is oriented parallel to the shunt resistor's rear surface and is soldered in place. Both electrical connector pins 173 and 174 maintain a perpendicular orientation to this surface. The support part 172 acts as a common junction, interfacing between the two connector pins and the base part. All connections including the pins to the support part and the support part to the base, are solidified through soldering. As with terminal 180, all components of terminal 170 are constructed from highly conductive materials to ensure optimal electrical performance.

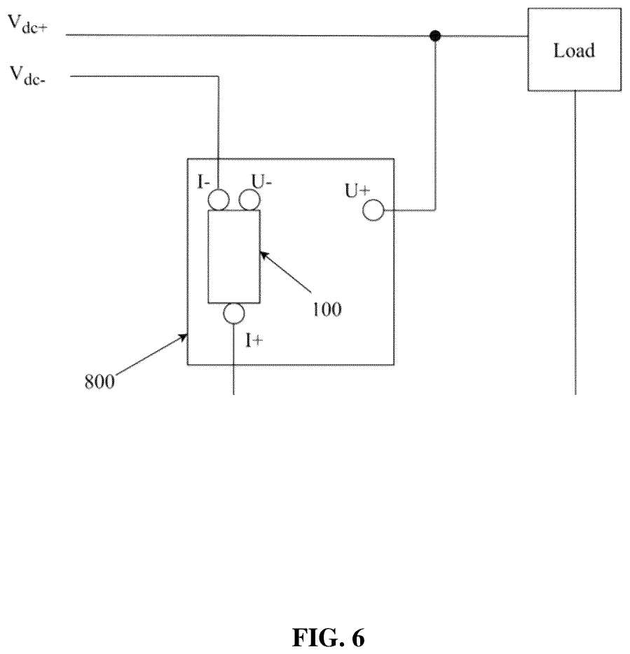

FIG. 6 illustrates the wiring diagram of a power meter 800, which embodies the present invention by integrating the innovative shunt 100. In this configuration, the terminal I+corresponds to the electrical connector pin 183, while terminals I-and U-correspond to electrical connector pins 173 and 174, respectively. This arrangement demonstrates the practical application of the dual-pin design in terminal 170.

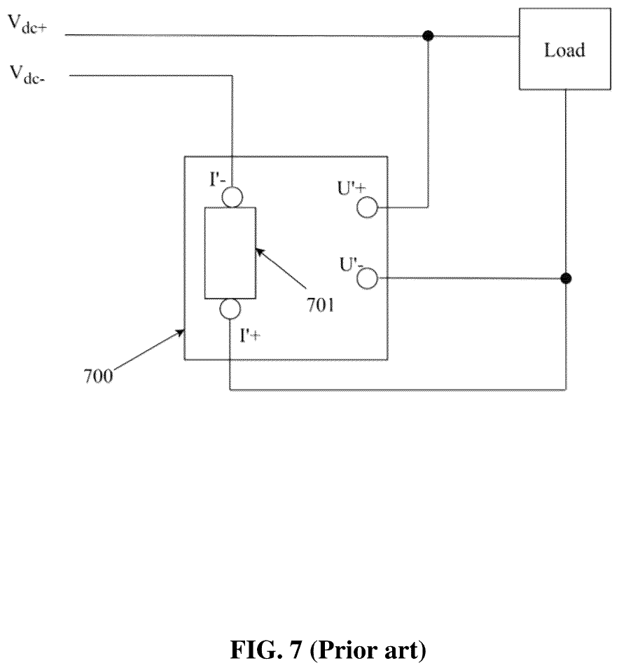

In contrast, FIG. 7 depicts the wiring diagram of a prior art power meter 700, which incorporates a traditional shunt 701. This conventional design necessitates four distinct terminals: I′+, I′−, U′+, and U′−. The present invention, as illustrated in FIG. 6, eliminates the need for a separate U-terminal. This simplification in terminal configuration offers significant advantages in PCB layout design, potentially reducing complexity, space requirements, and manufacturing costs.

The innovative terminal design and wiring configuration presented in this invention represent a substantial improvement over prior art, offering enhanced efficiency in power measurement applications while simplifying the overall system architecture. This advancement holds promise for more compact and cost-effective power metering solutions in various electrical systems.

The present invention also presents an advanced power meter designed for precise energy consumption measurement, particularly suitable for high-current applications such as electric vehicle charging stations. This power meter incorporates a modular design with a replaceable shunt resistor, allowing for easy maintenance and adaptability to various current ranges.

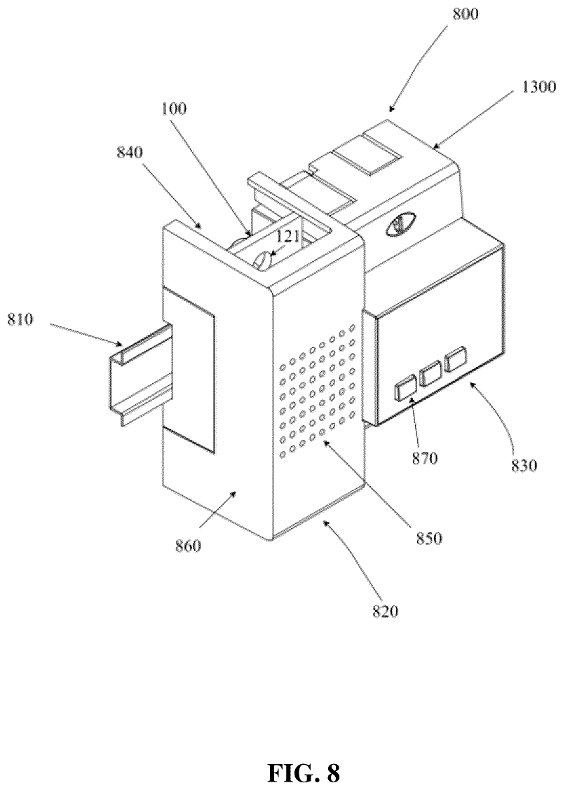

The power meter, designated as 800 in the accompanying figures, comprises two main functional components: a shunt part 820 and a meter part 830. These components work in tandem to provide accurate energy consumption data for electrically powered devices. The overall structure and arrangement of these components can be best understood through a comprehensive examination of FIG. 8 through FIG. 13.

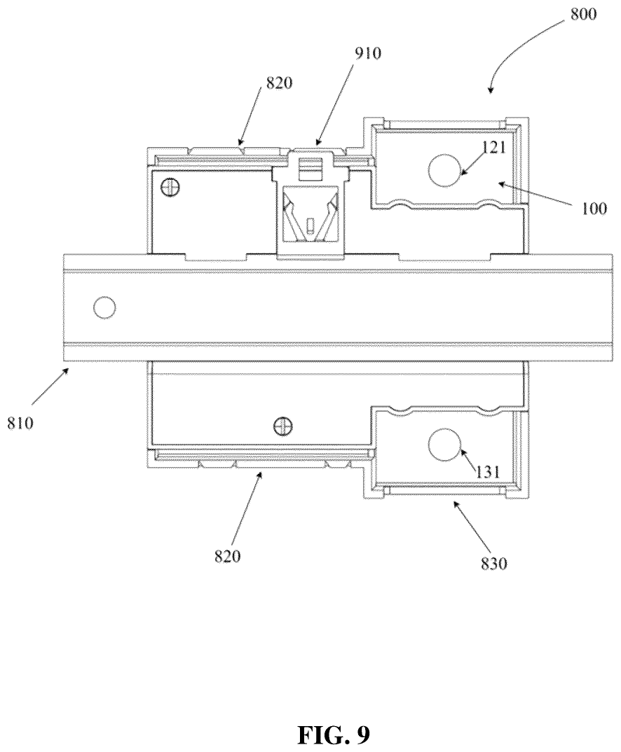

FIG. 8 presents a top left front perspective view of the power meter 800 installed on a DIN rail 810, while FIG. 9 offers a rear view of the same configuration. These figures illustrate the compact and integrated nature of the design, showcasing how the power meter 800 is designed to fit seamlessly into standard electrical installations.

The rear view in FIG. 9 reveals a crucial component of the power meter's mounting system: a clip 910. The clip 910 enables the power meter 800 to be easily installed on a standard DIN rail, ensuring compatibility with existing infrastructure and simplifying installation processes. This mounting system reduces setup time by up to 60% compared to traditional wall-mounted meters, allowing for quick and standardized installation in various electrical environments.

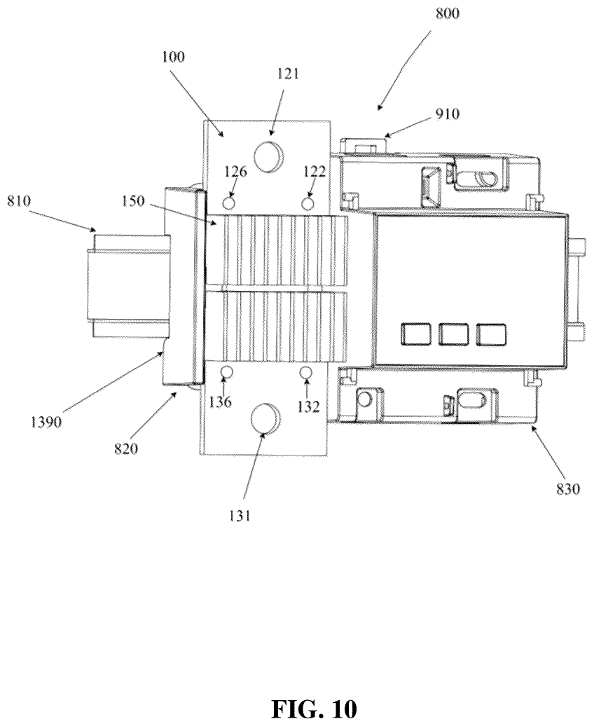

FIG. 10 provides a top left front perspective view of the power meter 800 with the cover 860 removed, offering insight into the internal configuration. This view reveals the shunt part 820, which consists of the shunt resistor 100 mounted on a shunt support platform 1390. The shunt resistor 100 is the core component responsible for measuring the current passing through the electrically powered device. It is engineered to handle high currents while providing accurate voltage readings proportional to the current flow.

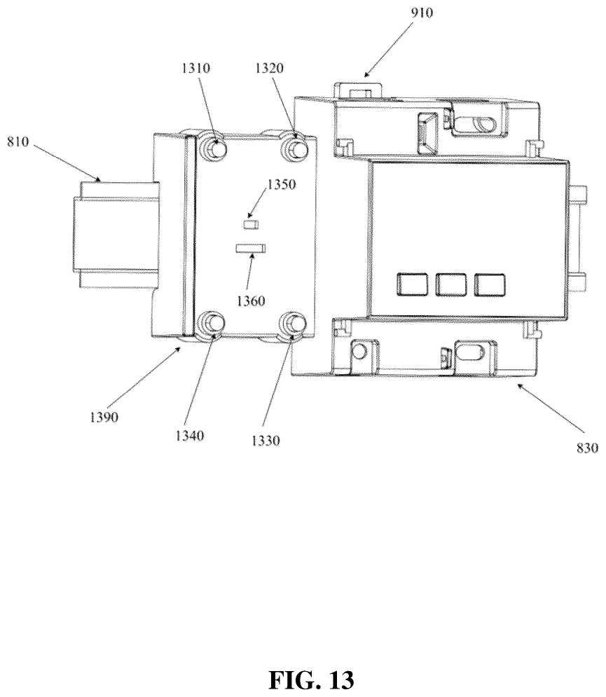

The shunt support platform 1390, visible in both FIG. 10 and FIG. 13, is fabricated from a high-temperature resistant polymer capable of withstanding continuous operating temperatures of up to 125° C. without deformation. FIG. 13, which shows the power meter with both the cover 860 and shunt resistor 100 removed, reveals that the support platform 1390 and meter part 830 are integrally formed. This unified structure minimizes potential points of failure and improves overall reliability.

FIG. 13 also exposes the details of the shunt mounting system. Four bolts (1310, 1320, 1330, and 1340) are positioned at the corners of the support platform 1390. These bolts correspond to mounting holes (126, 122, 136, and 132) on the shunt resistor 100, enabling secure and precise attachment.

Two rectangular openings (1350 and 1360) are placed in the middle of the support platform 1390. The larger opening 1360 accommodates the measurement terminal 170 of the shunt resistor 100, while the smaller opening 1350 allows for the passage of measurement terminal 180.

A multi-layer PCB board, housed within the support platform 1390 and meter part 830, utilizes FR-4 substrate with a Tg of at least 170° C. for improved thermal stability. The measurement terminals 170 and 180 of the shunt resistor 100 are designed to securely fasten to this PCB board through connections. This design facilitates the efficient transfer of voltage signals from the shunt resistor 100 to the meter part 830 for processing. The PCB layout is optimized to minimize electromagnetic interference, with ground planes and careful signal routing to maintain signal integrity.

The shunt resistor 100, as seen in FIG. 10, features openings 121 and 131 on its top and bottom parts, respectively. These openings are engineered to connect with bus bars that carry input and output current signals, allowing the shunt to accurately measure current flow. In some embodiments, the openings are designed to accommodate bus bars up to 30 mm wide and 10 mm thick, capable of handling currents up to 600 A continuous and 1000 A for short durations (≤1 second).

The meter part 830, visible in FIGS. 13 and 10, contains the complete circuitry required to measure the amount of electric energy consumed by an electrically powered device over a time interval. It incorporates a high-resolution analog-to-digital converter (ADC) with a sampling rate of at least 4000 samples per second, enabling accurate measurement of complex waveforms and harmonics up to the 50th order. This high sampling rate ensures compliance with IEC 62053-22 Class 0.5S accuracy standards for active energy measurement.

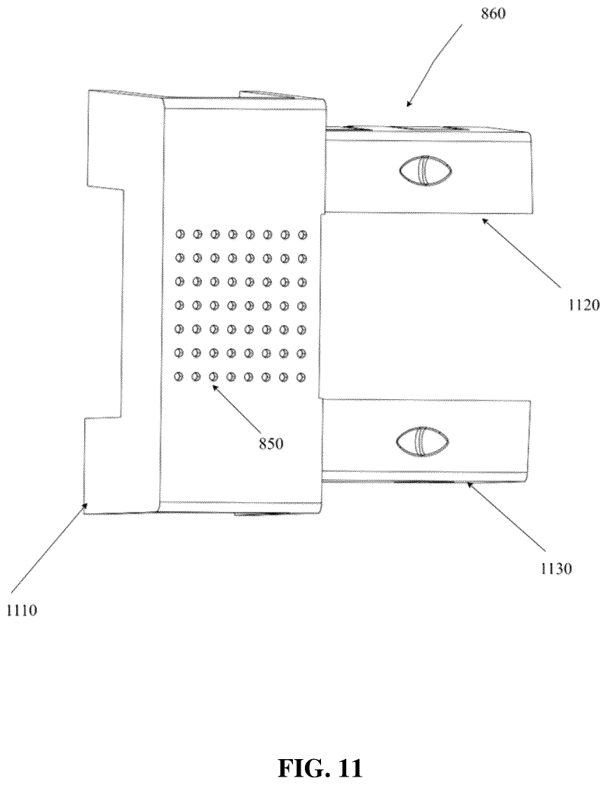

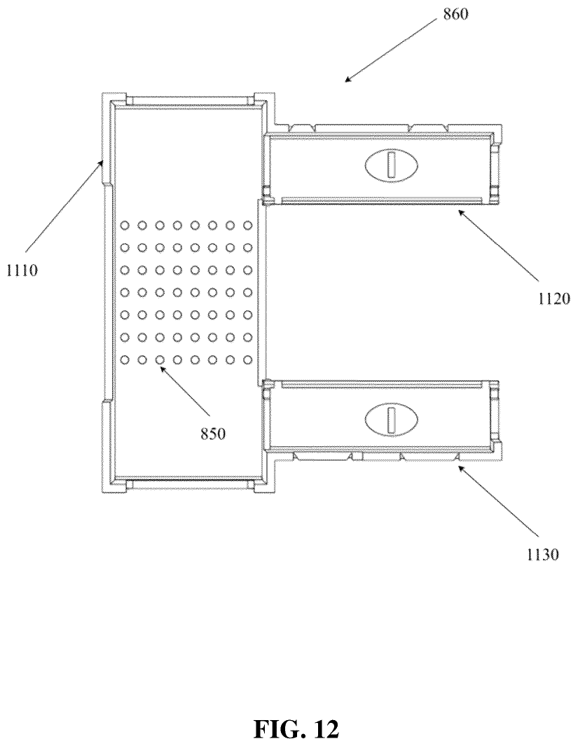

FIG. 11 and FIG. 12 illustrate the front perspective and rear views of the cover 860, respectively. The cover consists of a left part 1110 and right parts 1120 and 1130, which are integrally formed. The left part 1110 is designed to encase the support platform 1390, while the right parts 1120 and 1130 protect the meter part 830. This U-channel shaped cover is constructed from flame-retardant polycarbonate material, meeting UL94 V-0 standards for fire safety. The cover design allows for easy removal during maintenance or shunt replacement, featuring a snap-fit mechanism that can withstand at least 500 cycles of opening and closing without degradation.

To address thermal management, the left part 1110 of the cover incorporates several through holes 850, each 5 mm in diameter, arranged in a grid pattern with 10 mm spacing. These holes, visible in FIGS. 11 and 12, facilitate heat dissipation from the shunt resistor 100, allowing for natural convection cooling that can dissipate heat under normal operating conditions.

The modular construction of the power meter 800, as evidenced by the easily removable shunt resistor 100 shown in FIG. 10 and FIG. 13, allows for easy maintenance and upgrades without replacing the entire unit. This design significantly reduces long-term operational costs and improves the device's lifespan. The ability to exchange shunt resistors easily enables the power meter 800 to be adapted for various current ranges, from 50 A to 4000 A full scale, making it suitable for a wide range of applications from residential to industrial use.

The use of a high-precision shunt resistor, coupled with advanced signal processing in the meter part, ensures accurate energy consumption measurements, critical for billing and energy management purposes. The meter achieves an overall accuracy of ±0.5% across its full measurement range, from 5% to 120% of nominal current, and maintains this accuracy over a temperature range of −40°C. to +60° C.

The direct connection of shunt resistor protrusions to the internal PCB, minimizes signal loss and interference, contributing to the overall accuracy of the power meter 800. The analog front-end of the meter part features a low-noise instrumentation amplifier with a common-mode rejection ratio (CMRR) of at least 100 dB, ensuring accurate measurements even in electrically noisy environments.

This improved power meter design, as comprehensively illustrated in FIG. 8 through FIG. 13, represents a significant advancement in energy measurement technology. It offers a combination of accuracy, adaptability, and ease of maintenance that addresses the evolving needs of modern electrical systems. Its modular nature, combined with high precision and robust construction, positions it as a versatile solution for a wide range of energy monitoring applications in the increasingly complex landscape of power distribution and management.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

What is claimed is:

1. A shunt resistor for current measurement, comprising:
a resistance element having a first end and a second end;
a first electrode connected to the first end of the resistance element;
a second electrode connected to the second end of the resistance element;
wherein the resistance element includes recessed portions on opposite side surfaces extending inward towards a center of the shunt resistor, the recessed portions configured to reduce stress concentration and thermal expansion differences;
a first measurement terminal attached to the first electrode; and
a second measurement terminal attached to the second electrode;
wherein the first electrode and the second electrode are arranged in a first direction corresponding to a length of the shunt resistor, and the recessed portions extend in a second direction perpendicular to the first direction.

2. The shunt resistor of claim 1, wherein the first measurement terminal includes a base part parallel to a surface of the shunt resistor; two electrical connector pins perpendicular to the surface of the shunt resistor; and a support part connecting the base part to the two electrical connector pins.

3. The shunt resistor of claim 1, wherein the second measurement terminal includes a base part parallel to a surface of the shunt resistor; one electrical connector pin perpendicular to the surface of the shunt resistor; and a support part connecting the base part to the one electrical connector pin.

4. The shunt resistor of claim 1, further comprising a heat sink positioned above a front surface of the shunt resistor, with an insulating film interposed between the heat sink and the shunt resistor.

5. The shunt resistor of claim 1, wherein the recessed portions are rectangular when viewed perpendicular to both a length direction and a width direction of the shunt resistor.

6. The shunt resistor of claim 1, wherein the first and second electrodes are made of copper and the resistance element is made of a Cu-Mn alloy.

7. The shunt resistor of claim 1, wherein the first and second electrodes each include at least one opening configured to facilitate connection with bus bars.

8. A power meter for installation on a DIN rail, comprising:
a shunt part including a shunt resistor mounted on a support platform;
a meter part configured to compute electric energy consumed by an electrically powered device based on voltage signals received from the shunt resistor; and
a protective cover designed to enclose the shunt part and the meter part.

9. The power meter of claim 8, wherein the support platform and the meter part are integrally formed to enhance structural integrity and simplify installation on the DIN rail.

10. The power meter of claim 8, wherein the support platform includes two rectangular openings configured to accommodate measurement terminals from the shunt resistor.

11. The power meter of claim 10, wherein a first opening is larger and configured to accommodate a first measurement terminal having two electrical connector pins, and a second opening is smaller and configured to accommodate a second measurement terminal having one electrical connector pin.

12. The power meter of claim 8, wherein the protective cover is detachable and U-channel shaped, comprising a left part designed to encase the support platform and right parts designed to protect the meter part.

13. The power meter of claim 12, wherein the left part of the cover incorporates through holes arranged in a grid pattern to facilitate heat dissipation from the shunt resistor.

14. The power meter of claim 8, further comprising a clip for mounting the power meter onto the DIN rail, wherein the clip facilitates easy attachment and detachment of the power meter from the DIN rail.

15. The power meter of claim 8, further comprising a multi-layer printed circuit board (PCB) within the support platform and meter part, wherein measurement terminals of the shunt resistor are fastened to the PCB.

16. The power meter of claim 8, wherein the shunt resistor is replaceable, allowing for adaptation to various current ranges.
